(19) United States
(12) Patent Application Publication
(10) Pub. No.: US 2013/0071962 A1
(43) Pub. Date: Mar. 21, 2013

(54) Method of Manufacturing TFT Array Substrate and TFT Array Substrate

(71) Applicant: Shijian Qin, Shenzhen (CN)

(72) Inventor: Shijian Qin, Shenzhen (CN)

(21) Appl. No.: 13/375,564

(22) PCT Filed: Sep. 30, 2011
(86) PCT No.: PCT/CN11/80504

§ 371 Date: Dec. 1, 2011

(30) Foreign Application Priority Data
Sep. 20, 2011 (CN) 201110280163.6

(51) Int. Cl. H01L 33/08

(52) U.S. Cl. 438/34; 257/E33.053

(57) ABSTRACT

The invention discloses a method of manufacturing TFT array substrate and a TFT array substrate, wherein the manufacturing method comprises the following steps: sequentially depositing a metal film, a insulating layer, and a semiconductor layer, and manufacturing a gate line and a gate electrode using a composition method; depositing a insulating layer, and manufacturing a channel region protecting layer using the composition method; sequentially depositing a doped semiconductor layer and a metal layer; forming a source electrode, a drain electrode and a data line using the composition method; and cutting the doped semiconductor layer and the metal layer to form an energizing channel; and depositing an ITO layer, and forming a pixel electrode by the ITO layer using the composition method. Because four-composition technologies are used by the invention, the gate electrode, the gate line, and the active layer are manufactured by the single-composition technology, and the pixel electrode, the data line, the source electrode, the drain electrode, the channel and the like are directly formed by the completely developed photoetching or dry etching method; the manufacturing difficulty of the array substrate is greatly reduced; the production cost of the array substrate is reduced; and the production efficiency is increased. The TFT component formed by the array substrate is of back-channel protection type structure in favour of reduction of the off-state current of the component.

### TECHNICAL FIELD

The invention relates to the field of liquid crystal displays (LCDs), and more particularly to a method of manufacturing a thin-film transistor (TFT) array substrate of LCD panels as well as a TFT array substrate.

### BACKGROUND

An LCD panel is one of the crucial components of the LCD, and the existing TFT-LCD panels are widely used in the LCD because of such advantages as low power consumption, small volume, no radiation and the like.

An LCD panel includes an array substrate and a color film (CF) substrate, and a liquid crystal is positioned between the array substrate and the CF substrate. At present, a TFT array substrate is manufactured by forming a layout required by the structure on a glass substrate by a composition technology to form a TFT component and a wiring related thereto. Because the wiring of the TFT component and the glass substrate are provided with multiple layers, the array substrate must be manufactured by implementing many times of composition technologies. The initial array substrate is manufactured by implementing seven times of composition technologies. But at present, with the development of technologies, the array substrate can be manufactured by only implementing four times of composition technologies through the technique development and improvement. Thus, the manufacturing cost of the LCD panel is greatly reduced, and the production efficiency increased. However, conventional four-composition technologies and the processes involved therein are complicated, in which a half exposure technique is required, thereby improving the manufacturing difficulty. In addition, because an OC layer is required as an insulating layer, the production difficulty is increased.

### SUMMARY

The aim of the invention is to provide a TFT array substrate manufacturing method with high efficiency and low manufacturing difficulty.

The purpose of the invention is achieved by the following technical schemes.

A TFT array substrate manufacturing method comprises the following steps:

A. Sequentially depositing a metal film, a insulating layer, and a semiconductor layer, and then manufacturing a gate line and a gate electrode using a composition method;

B. Depositing a insulating layer and manufacturing a channel region protecting layer using the composition method;

C. Sequentially depositing a doped semiconductor layer and a metal layer, forming a source electrode, a drain electrode, and a data line using the composition method, and cutting the doped semiconductor layer and the metal layer to form an energizing channel; and

D. Depositing an ITO layer and forming a pixel electrode by the ITO layer using the composition method.

Preferably, in the step A, the metal film is formed using a sputter method, and thereafter a SiNx insulating layer and an a-Si semiconductor layer are sequentially deposited on the metal film using a chemical vapor deposition (CVD). The metal film is used for manufacturing the gate electrode and the gate line. The film obtained using the sputter method has good combinability, high purity, and good compactability, satifying the requirement of the gate electrode and the gate line. The CVD for forming the insulating layer and the semiconductor layer has a simple process.

Preferably, in the step A, the gate line and the gate electrode are formed using a photoetching method as the composition method. The gate electrode, the gate line, and an active layer are conveniently formed using the photoetching method.

Preferably, in the step B, the insulating layer is a SiNx layer, and the SiNx layer is deposited and formed on the semiconductor layer using the CVD. The metal film obtained using the sputter method has good combinability, high purity, and good compactability. Thus, the insulating layer to be used as the back-channel protection has better internal structure and effect.

Preferably, in the step B, the TFT channel region protecting layer is formed using the photoetching method as the composition method.

Preferably, in the step C, N+a-Si is deposited using the CVD to form the doped semiconductor layer, and the metal layer is deposited on the doped semiconductor layer using the sputter method. The film obtained using the sputter method has good combinability, high purity, and good compactability.

Preferably, in the step C, the TFT source electrode, the drain electrode, and the data line are formed using the photoetching method as the composition method. The source electrode, the drain electrode, and the data line are conveniently formed using the photoetching method.

Preferably, in the step C, the doped semiconductor layer is out using a dry etching method to form the energizing channel. The dry etching process is simple and quick.

Preferably, in the step D, the ITO layer is deposited and formed using the sputter method.

Preferably, in the step D, the pixel electrode is formed by the ITO layer using the photoetching method as the composition method; the pixel electrode is connected with the drain electrode; and the ITO layers having the same layout as that of the pixel electrode are respectively formed on the data line, the source electrode, and the drain electrode.

A TFT array substrate manufactured using the aforementioned TFT array substrate manufacturing method.

Because four-composition technologies are used by the invention, the gate electrode, the gate line, and the active layer are manufactured by the single-composition technology, and the pixel electrode, the data line, the source electrode, the drain electrode, and the channel are directly formed by the completely developed photoetching or dry etching methods without using the half exposure technique and without using the OC layer as the insulating layer; thus, the manufacturing difficulty of the array substrate is greatly reduced, and the material involved therein is reduced. Thus, the production cost of the array substrate is reduced, and the production efficiency increased. The TFT component formed by the array substrate is of a back-channel protection type structure in favor of reduction of the off-state current of the component.

### BRIEF DESCRIPTION OF FIGURES

FIG. 1 is a schematic diagram of a structure formed in step A of one embodiment of the invention;

FIG. 2 is a schematic diagram of a structure formed in step B of one embodiment of the invention;

FIG. 3 is a schematic diagram of a structure formed in step C of one embodiment of the invention;

FIG. 4 is a schematic diagram of a structure formed in step D of one embodiment of the invention; and

FIG. 5 is a schematic diagram of a manufacturing flow of one embodiment of the invention.

Wherein: 1. glass substrate; 2. metal film; 3. insulating layer; 4. semiconductor layer; 5. SiNx layer; 6. doped semiconductor layer; 7. source electrode; 8. drain electrode; 9. ITO layer.

### DETAILED DESCRIPTION

The invention will further be described in detail in accordance with the figures and the preferred embodiments.

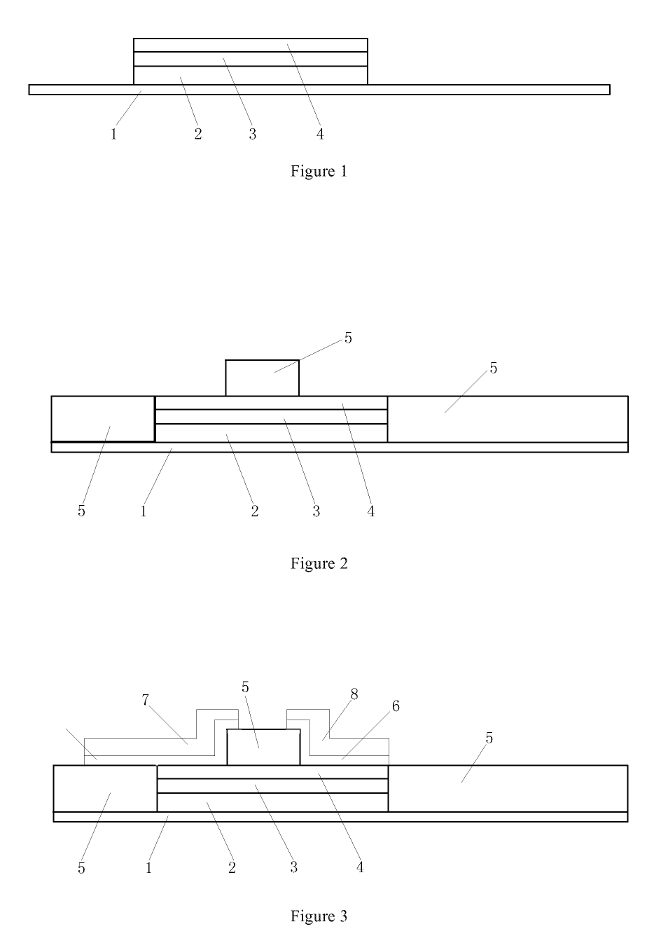

As shown in FIG. 1 to FIG. 5, a method for manufacturing a TFT array substrate comprises the following steps:

Step A: As shown in FIG. 1, cleaning a glass substrate with a cleaning liquid, for example, pure water or a hot sulphuric acid and the like; forming a layer of metal film 2 on the glass substrate 1 using a sputter method for preparation of a gate electrode; and sequentially depositing a SiNx insulating layer 3 and an a-Si semiconductor layer 4 on the metal film using a CDV for preparation of an active layer; then, forming a gate line and the gate electrode using a photoetching method. Specifically, applying a photoresist, for example, a photopolymer and the like, onto the a-Si semiconductor layer; exposing and developing the photoresist to a desired shape; and forming the gate line and the gate electrode by etching. in the step, the layout of the gate electrode, the gate line, and the active layer are formed by single-composition technology, the number of times of composition is reduced, and the production efficiency increased.

Step B: As shown in FIG. 2, depositing a SiNx layer 5 as an insulating layer on the a-Si semiconductor layer using the CVD, and forming a TFT channel region protecting layer using the photoetching method again.

Step C: As shown in FIG. 3, depositing N+a-Si using the CVD to form a doped semiconductor layer 6; depositing a layer of metal film on the N+a-Si layer using the sputter method; forming a TFT source electrode 7, a drain electrode 8, and a data line using the photoetching method; and cutting the N+a-Si layer using a dry etching method to form an energizing channel.

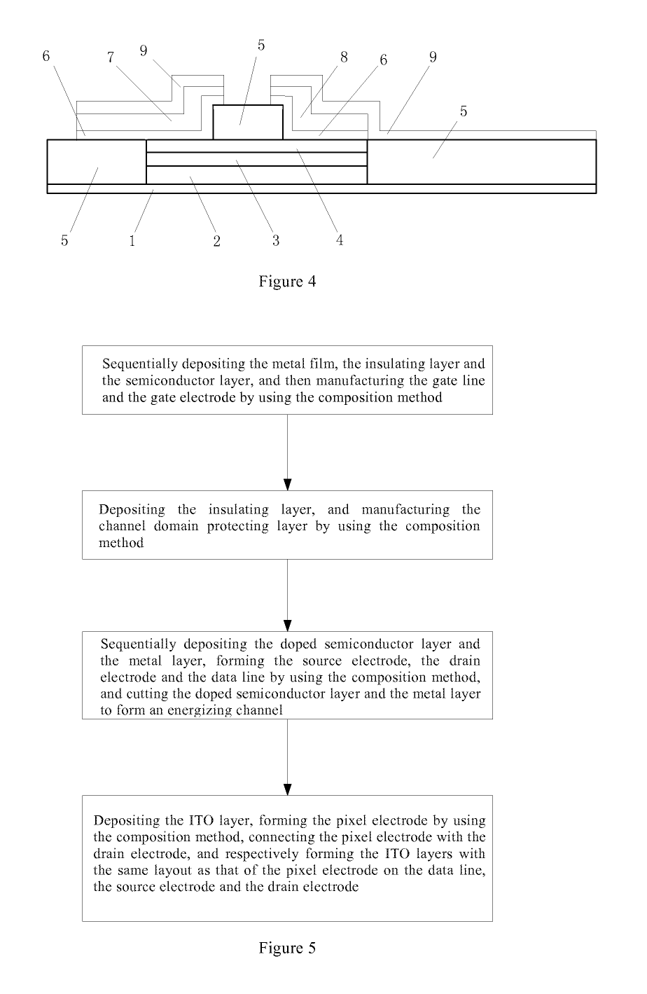

Step D, as shown in FIG. 4, depositing an ITO layer 9 using the sputter method; manufacturing and forming an ITO pixel electrode using the photoetching method; connecting the ITO pixel electrode with the drain electrode 8; and respectively forming the ITO layers 9 having the same layout as that of the pixel electrode on the data line, the source electrode, and the drain electrode.

In accordance with the aforementioned manufacturing method, an array substrate with a back-channel protection type TFT component is obtained, as shown in FIG. 4: a metal film 2 is arranged on a glass substrate 1; and a SiNx insulating layer 3 and an a-Si semiconductor layer 4 are respectively arranged on the metal film 2, to form a gate electrode and an active layer (insulating layer 3 and semiconductor layer 4) of the TFT component. A SiNx layer 5 is arranged on the active layer to be used as an insulating layer; a cut doped semiconductor layer 6, which makes the channel insulating and protecting layer be exposed, and a second metal layer (corresponding to a source electrode 7 and a drain electrode 8 in FIG. 4) are arranged on the SiNx layer 5 to form the source electrode 7 and the drain electrode 8; and an ITO layers 9 are arranged on the source electrode 7 and the drain electrode 8 to form an ITO pixel electrode. In the embodiment, the formed TFT component is of the back-channel protection type structure in favor of reduction of the off-state current of the component.

The invention is described in detail in accordance with the above contents with the specific preferred embodiments. However, this invention is not limited to the specific embodiments. For the ordinary technical personnel of the technical field of the invention, on the premise of keeping the conception of the invention, the technical personnel can also make simple deductions or replacements, and all of which should be considered to belong to the protection scope of the invention.

We claim:

1, A method of manufacturing thin-film transistor (TFT) array substrate comprises the following steps:
A. sequentially depositing a metal film, a insulating layer, and a semiconductor layer, and then manufacturing a gate line and a gate electrode using a composition method;
B. depositing a insulating layer and manufacturing a channel region protecting layer using said composition method;
C. sequentially depositing a doped semiconductor layer and a metal layer; forming a source electrode, a drain electrode, and a data line using said composition method; and cutting said doped semiconductor layer and said metal layer to form an energizing channel; and
D. depositing an ITO layer and forming a pixel electrode by said ITO layer using said composition method.

2, The method of claim 1, wherein in said step A, said metal film is formed using a sputter method, and thereafter a SiNx insulating layer and an a-Si semiconductor layer are sequentially deposited on said metal film using a chemical vapor deposition (CVD).

3, The method of claim 2, wherein in said step A, said gate line and said gate electrode are formed using a photoetching method as said composition method.

4, The method of claim 1, wherein in said step B, said insulating layer is a SiNx layer, and said SiNx layer is deposited and formed on said semiconductor layer using said CVD.

5, The method of claim 4, wherein in said step B, said TFT channel region protecting layer is formed using said photoetching method as said composition method.

6, The method of claim 1, wherein in said step C, N+a-Si is deposited using said CVD to form said doped semiconductor layer, and said metal layer is deposited on said doped semiconductor layer using said sputter method.

7, The method of claim 6, wherein in said step C, said TFT source electrode, said drain electrode, and said data line are formed using said photoetching method as said composition method.

8, The method of claim 6, wherein in said step C, said doped semiconductor layer is cut using a dry etching method to form said energizing channel.

9, The method of claim 1, wherein in said step D, said ITO layer is deposited and formed using said sputter method.

10, The method of claim 9, wherein in said step D, said pixel electrode is formed by said ITO layer using said photoetching method as said composition method; said pixel electrode is connected with said drain electrode; and ITO layers having the same layout as that of said pixel electrode are respectively formed on said data line, said source electrode, and said drain electrode.

11, A TFT array substrate manufactured using the method of manufacturing TFT array substrate of claim 1, wherein said method comprises the following steps:
A. sequentially depositing said metal film, said insulating layer, and said semiconductor layer, and then manufacturing said gate line and said gate electrode using said composition method;
B. depositing the insulating layer and manufacturing said channel region protecting layer using said composition method;
C. sequentially depositing said doped semiconductor layer and said metal layer; forming said source electrode, said drain electrode and said data line using said composition method; and cutting said doped semiconductor layer and said metal layer to form said energizing channel; and
D. depositing said ITO layer and forming said pixel electrode by said ITO layer using said composition method.

12, The TFT array substrate manufactured using the method of manufacturing TFT array substrate of claim 11, wherein in said step A, said metal film is formed using said sputter method, and said SiNx insulating layer and said a-Si semiconductor layer are sequentially deposited on said metal film using said CVD.

13, The TFT array substrate manufactured using the method of manufacturing TFT array substrate of claim 12, wherein in said step A, said gate line and said gate electrode are formed using said photoetching method as said composition method.

14, The TFT array substrate manufactured using the method of manufacturing TFT array substrate of claim 11, wherein in said step B, said insulating layer is said SiNx layer, and said SiNx layer is deposited and formed on said semiconductor layer using said CVD.

15, The TFT array substrate manufactured using the method of manufacturing TFT array substrate of claim 14, wherein in said step B, said TFT channel region protecting layer is formed using said photoetching method as said composition method.

16, The TFT array substrate manufactured using the method of manufacturing TFT array substrate of claim 11, wherein in said step C, said N+a-Si is deposited using said CVD to form said doped semiconductor layer, and said metal layer is deposited on said doped semiconductor layer using said sputter method.

17, The TFT array substrate manufactured using the method of manufacturing TFT array substrate of claim 16, wherein in said step C, said TFT source electrode, said drain electrode, and said data line are formed using said photoetching method as said composition method.

18, The TFT array substrate manufactured using the method of manufacturing TFT array substrate of claim 16, wherein in said step C, said doped semiconductor layer is cut using said dry etching method to form said energizing channel.

19, The TFT array substrate manufactured using the method of manufacturing TFT array substrate of claim 11, wherein in said step D, said ITO layer is deposed and formed using said sputter method.

20, The TFT array substrate manufactured using the method of manufacturing TFT array substrate of claim 19, wherein in said step D, said pixel electrode is formed by said ITO layer using said photoetching method as said composition method; said pixel electrode is connected with said drain electrode; and ITO layers having the same layout as that of said pixel electrode are respectively formed on said data line, said source electrode, and said drain electrode.
